(19) United States
(12) Patent Application Publication
(10) Pub. No.: US 2014/0299059 A1
(43) Pub. Date: Oct. 9, 2014

(54) VAPOR DELIVERY SYSTEM

(71) Applicant: OFS Fitel, LLC, Norcross, GA (US)

(72) Inventors: David D. Braganza, Southbridge, MA (US); Siddarth Nagarkatti, Acton, MA (US)

(73) Assignee: OFS Fitel, LLC, Norcross, GA (US)

(21) Appl. No.: 14/243,264

(22) Filed: Apr. 2, 2014

Related U.S. Application Data
(60) Provisional application No. 61/808,033, filed on Apr. 3, 2013.

(51) Int. Cl. C23C 16/455

(52) U.S. Cl. CPC C23C 16/45502
USPC 118/723 R; 137/561 R

(57) ABSTRACT

Vapor delivery systems for chemical depositions are shown in which the vapor delivery systems are capable of simultaneous buffering and fast response. The vapor delivery systems achieved the functionality using a two-volume system. The first volume mainly functions as a buffer to stabilize perturbations in vapor flow upstream. The second volume is smaller than the first volume so that the second volume responds to a change in vapor flow quickly. Optionally, a fixed flow restrictor is connected to the second volume and the fixed flow restrictor buffers downstream fluctuations.

### CROSS REFERENCE TO RELATED APPLICATION

The present application claims the priority benefit of United States Provisional Patent Application Serial No. 61/808,033, entitled “VAPOR DELIVERY SYSTEM,” filed on Apr. 3, 2013, which is owned by the assignee of the present application, and which is incorporated herein by reference in its entirety.

### BACKGROUND

1. Field of the Disclosure

The present invention relates to a vapor delivery system for chemical deposition. More specifically, the invention relates to a vapor delivery system for manufacturing optical fiber preforms.

2. Description of Related

Optical fibers are made from optical fiber preforms. There are many known methods to manufacture the optical fiber preforms. One of them is Plasma Chemical Vapor Deposition (PCVD) process. In PCVD, one or more chemical reactants are delivered to an inner surface of a substrate tube to make the preform. Any desired chemical reactants must be converted from liquid to vapor before they are delivered to the substrate tube. Current vapor delivery systems convert the chemical reactants to vapor, however it is difficult for the current system to simultaneously buffer and respond quickly to a change in the flow of chemical reactants. Therefore, there is a need for a vapor delivery system that is capable of simultaneous buffering and fast response.

### SUMMARY

The present disclosure provides vapor delivery systems for simultaneous buffering and fast response to a change in the vapor flow. Briefly described, for some embodiments, the vapor delivery system comprises two volumes to deliver the vaporized chemical reactants to downstream. The vaporized chemical reactants pass through a large first volume and then a small second volume before they are delivered to the downstream. By having a dual-volume system, the vapor delivery systems can simultaneously buffer and respond quickly to a change in the vapor flow.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a diagram showing an exemplary PCVD system.

FIG. 2 is a diagram showing one embodiment of a vapor delivery system that is capable of simultaneous buffering and fast response.

FIG. 3 is a graph showing a response time of one embodiment of the vapor delivery system to a change in vapor flow.

FIG. 4 is a graph showing a response time of one embodiment of the vapor delivery system to another change in vapor flow.

FIG. 5 is a graph showing a response time of one embodiment of the vapor delivery system to another change in vapor flow.

FIG. 6 is a graph showing a response time of one embodiment of the vapor delivery system to another change in vapor flow.

### DETAILED DESCRIPTION OF THE EMBODIMENTS

One way of manufacturing an optical fiber preform is known in the art as the Plasma Chemical Vapor Deposition (PCVD) process. According to this process, one or more doped or undoped glass layers are deposited onto the interior of a substrate tube using low-pressure plasma in the glass substrate tube. After the glass layers have been deposited onto the interior of the glass substrate tube, the glass substrate tube is subsequently contracted by heat and the process creates a solid rod. In one embodiment, the solid rod may be externally provided with an additional amount of glass (i.e., by means of an external vapor deposition process), or by using one or more preformed glass tubes, thereby obtaining a composite preform. From this preform, one end is heated and drawn down in diameter to produce optical fibers.

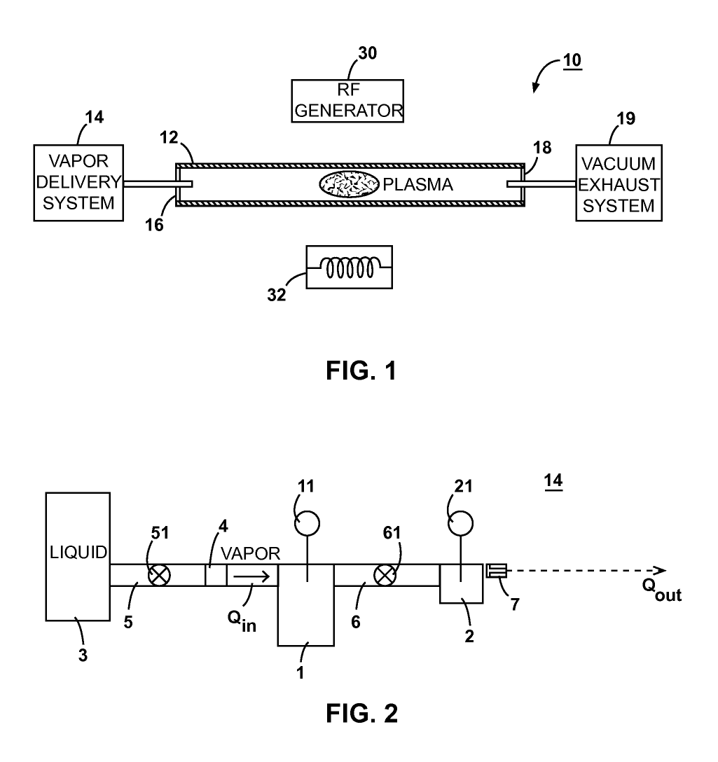

FIG. 1 illustrates an exemplary PCVD system 10. A glass tube 12 is used in the PCVD system 10 as the substrate tube within which the deposition will occur. The PCVD system 10 further comprises a vapor delivery system 14 to deliver one or more chemical reactants (such as GeCl₄, SiCl₄, C₂F₆, SiF₄ and O₂) into the substrate tube 12 through a first rotating seal 16 formed within a first end of tube 12. Although not shown in FIG. 1 (and not essential to the operation of the apparatus), substrate tube 12 is typically mounted in a glass working lathe that maintains the integrity of first seal 16 while rotating tube 12. The opposing end of tube 12 is coupled through a second rotating seal 18 to a vacuum exhaust system 19.

As shown in FIG. 1, an RF generator 30 is included in the PCVD system 10 and used to create a plasma of sufficient energy density within substrate 12 to provide the desired chemical reaction(s) with the delivered material. In most cases, generator 30 is mounted on a movable table (not show) to be traversed parallel to the axis of the mounted substrate tube. RF generator 30 comprises a resonant coil 32 that is positioned to surround a relatively short extent of tube 12, as shown in FIG. 1. An RF signal source (not shown) is coupled to resonant coil 32 and used to supply an RF signal thereto, thus creating the electro-magnetic field within tube 12. The combination of the incoming chemical reactants with the electro-magnetic field thus forms a plasma of an energy density sufficient to trigger the reaction and deposition of material on the inner surface of tube 12.

After the glass layers have been deposited onto the interior of the glass substrate tube 12 (sometimes called as soot preform), the glass substrate tube 12 is heated so that the glass substrate tube 12 subsequently contracted into a solid rod. The solid rod may be further processed to obtain an optical fiber preform. From this preform, one end is heated and drawn down in diameter to produce optical fibers.

In order to have desired optical and mechanical properties of an optical fiber, or to effect a change in the index of refraction of a vapor deposited soot preform for the optical fiber, the chemical composition of the vapors which are reacted to form the deposited soot may be varied. In the soot deposition process, the vapor mixture is oxidized/hydrolyzed at a burner to form a glass soot which is subsequently fused to form a high quality glass. Typically, SiCl₄ is the primary vapor constituent. One or more additional vapors can be supplied to the oxidation/flame hydrolysis burner, the one or more vapors comprising chemical precursors of dopants whose presence affects the properties of the glass being formed.

Any desired chemical precursors must be converted from liquid to vapor. Current vapor delivery systems only used a one-volume system to ultimately convert the liquid to vapor. The one-volume acts as a buffer; however, simultaneous buffering and fast response would be difficult with the current one-volume system.

The various embodiments disclosed herein overcome this difficulty by using a two-volume system for a vapor delivery system. The first volume is a large volume mainly functions as a buffer. The second volume is a small volume that quickly responds to a change in vapor flow. Optionally, a fixed flow restrictor is connected to the second volume and the fixed flow restrictor buffers downstream fluctuations.

Anything other than one-volume systems had not been approached due to cost and requirements for fast response and high accuracy were not required for previous applications. However, because optical fibers with more uniform and precise refractive index are in demand, there is a need to create a system that can achieve both buffering and fast response simultaneously. Furthermore, current systems have not used a choked flow element such as fixed flow restrictor after the volume system because little attention was made to downstream fluctuations.

Having generally described a vapor delivery system that satisfies both buffer and fast response conditions, reference is now made in detail to the description of the embodiments as illustrated in the drawings. While several embodiments are described in connection with these drawings, there is no intent to limit the disclosure to the embodiment or embodiments disclosed herein. On the contrary, the intent is to cover all alternatives, modifications, and equivalents. Furthermore, to the extent that some of the foundational information is described in detail in this application, one having ordinary skill in the art is presumed to have knowledge of that foundational information.

With this in mind, attention is turned to FIG. 2, which is a diagram showing one embodiment of a vapor delivery system 14 that is capable of simultaneous buffering and fast response. The vapor delivery system 14 incorporates a first volume 1 and a second volume 2 in accordance with the present invention. Predetermined liquid chemical reactants stored in one or more liquid tanks 3 are delivered to vaporizer 4 through one or more tubes 5 having a first control valve 51. After the chemical reactants are vaporized in the vaporizer 4, the vaporized chemical reactants are delivered to the first volume 1. The first volume 1 is relatively large volume compared to the second volume 2 and the first volume 1 mainly acts as a buffer to stabilize any perturbations in vapor flow upstream. A first pressure sensor 11 is connected to the first volume 1 to measure real-time pressure inside of the first volume 1 for any given time.

The vaporized chemical reactants delivered to the first volume Tare further delivered to the second volume 2 through one or more tubes 6 having a second gas control valve 61. The second volume 2 is a relatively small volume compared to the first volume 1 and the second volume 2 quickly responds to a change in vapor flow. A second pressure sensor 21 is connected to the second volume 2 to measure real-time pressure inside of the second volume 2 for any given time. After passing through the second volume 2, the vaporized chemical reactants are delivered downstream.

When pressure change in the first volume 1 is measured in the first pressure sensor 11, the first control valve 51 responds to the change and adjusts the flow to reduce disturbance. Similarly when pressure change in the second volume 2 is measured in the second pressure sensor 21, the second control valve 61 responds to the change and quickly adjusts the flow.

Optionally, a fixed flow restrictor 7 is connected to the second volume 2 and the vaporized chemical reactants are delivered to downstream through the fixed flow restrictor 7. The fixed flow restrictor buffers downstream fluctuations.

The appropriate size of the first volume 1 depends on the application. However, the first volume 1 must be larger than the second volume 2. A number of parameters that affects the size of the first volume 1 are, for example, the output flow rate (Qₒᵤₜ), accuracy required to minimize Qₒᵤₜ glitches when the vapor enters the first volume 1, type of control valve used for the first control valve 51, and type of liquid being used.

The second volume 2 is sufficiently small to allow quick response time. Preferably, the size of the second volume 2 is approximately 30% or less of the size of the first volume 1. For example, if the first volume 1 is 100cc in volume then the second volume should be less than 30cc in volume. More preferably, the size of the second volume 2 is approximately 5% or less of the size of the first volume 1. For example, if the first volume 1 is 160 cm³ in volume then the second volume 2 should be less than 7 cm³ in volume.

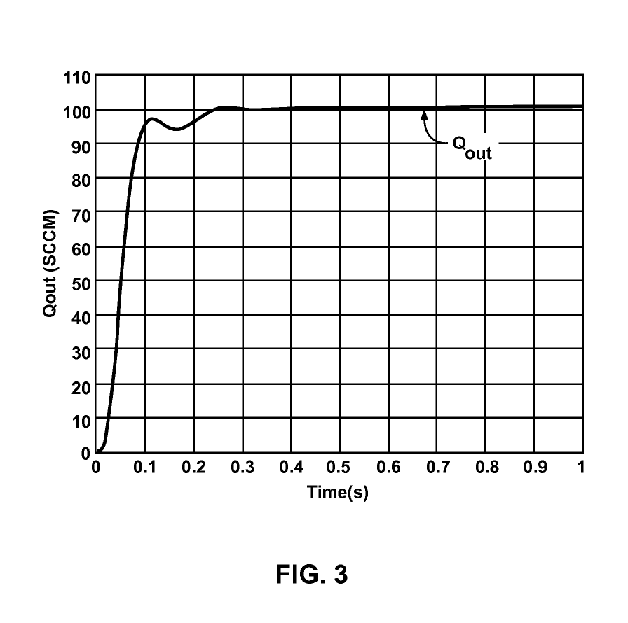

FIGS. 3 to 6 are simulation results of the disclosed vapor delivery system. FIGS. 3 to 6 show how the output flow (Qₒᵤₜ) of the system would behave under different conditions.

FIG. 3 shows an output flow response (Qₒᵤₜ) of the system when the flow setpoint is changed from 0 to 100 sccm (standard cubic centimeters per minute) instantaneously. When the flow setpoint is changed from 0 to 100 sccm instantaneously, the second control valve 61 in FIG. 2 responds to the step change and the second pressure sensor 21 detects the change in pressure inside the second volume 2 in FIG. 2. The response speed of the disclosed two-volume vapor delivery system is faster than that of a conventional one-volume system. Also, overshoot/undershoot before stabilization of the flow at 100 sccm is smaller than that of a conventional system.

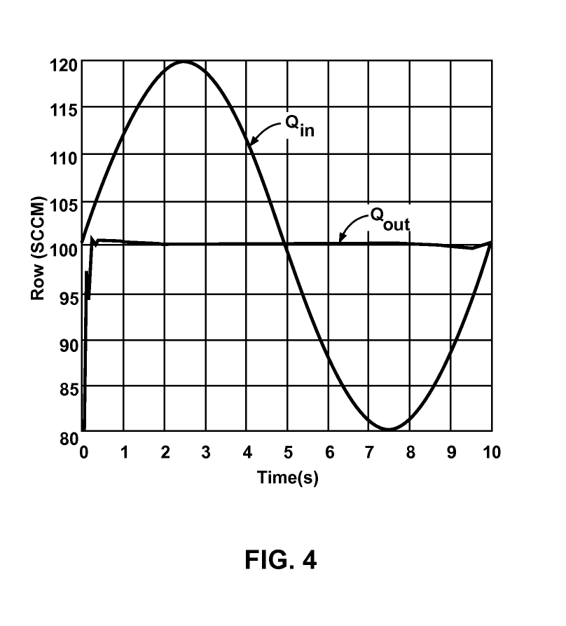

FIGS. 4 to 6 show how the disclosed vapor delivery system would respond to varying degrees of disturbances in the flow (Qᵢₙ) through the vaporizer 4 in FIG. 2. The disclosed vapor delivery system response is measured in terms of the output flow (Qₒᵤₜ) of the system.

FIG. 4 shows the disclosed vapor delivery system response when the disturbance in the flow (Qᵢₙ) is 0.1 Hz with a magnitude of +/−20% of the output flow setpoint. The vapor delivery system responds quickly to the disturbance and varies the control valves to ensure that the output flow (Qout) stays as close to the setpoint of 100 sccm.

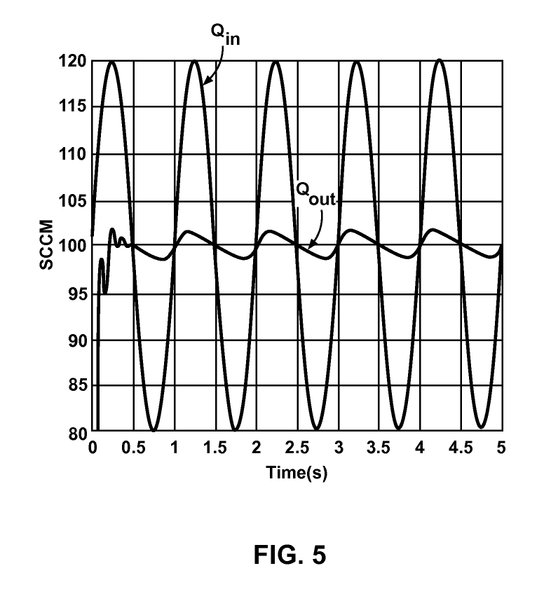

FIG. 5 shows the system response to a higher degree of disturbances in the flow (Qin) at 1 Hz with a magnitude of +/−20% of the output flow setpoint. Although the output flow (Qₒᵤₜ) varies, the system quickly responds to the disturbance and the output flow (Qₒᵤₜ) stays close to the setpoint of 100 sccm without going “unstable.”

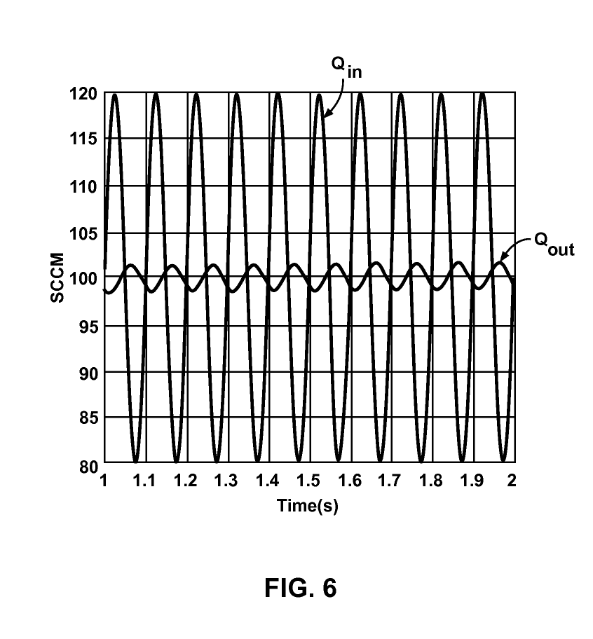

FIG. 6 shows the system response to an even higher degree of disturbances in the flow (Qᵢₙ) at 10 Hz with a magnitude of +/−20% of the output flow setpoint. Although the output flow (Qₒᵤₜ) varies, the output flow (Qₒᵤₜ) stays close to the setpoint of 100 sccm without going “unstable.”

Performance of an actual vapor delivery system may differ depending on the configuration of the vapor delivery system. For example, response time improves if the second volume is small and/or fast response pressure sensors are used to measure real-time pressure inside the first and second volumes. Overall performance increases if fast acting control valves are used and/or accurate pressure sensors are used.

As shown from the various embodiments and results disclosed in FIGS. 1 through 6, vapor delivery systems that are capable of simultaneous buffering and fast response are disclosed. The vapor delivery systems achieved the functionality using a two-volume system. The first volume mainly functions as a buffer to stabilize any perturbations in vapor flow upstream. The second volume is smaller than the first volume so that the second volume quickly responds to a change in vapor flow. Optionally, a fixed flow restrictor is connected to the second volume and the fixed flow restrictor buffers downstream fluctuations.

Although exemplary embodiments have been shown and described, it will be clear to those of ordinary skill in the art that a number of changes, modifications, or alterations to the disclosure as described may be made. The delivery system is applicable to any process where a vapor delivery system is required. Although specific attention was made to optical fiber preform manufacturing process, the vapor delivery system could be used in other manufacturing processes such as semiconductor manufacturing process or solar panel manufacturing process. In some processes, there may be no soot, no substrate tubes or no oxidation/flame. The system is uniquely suited for low pressure deposition processes where it is easy to maintain the choked flow regime.

In optical fiber preform manufacturing process, it should be appreciated that, although specific attention is made for PCVD process, the disclosed vapor delivery systems can be adjusted to achieve similar results in other methods to manufacture the optical fiber preforms such as Chemical Vapor Disposition (CVD), Modified Chemical Vapor Disposition (MCVD), Outside vapor deposition (OVD), Vapor phase axial deposition (VAD) and plasma-enhanced chemical vapor deposition (PECVD). Although the vapor delivery system is uniquely suited for low pressure deposition processes, it may be used for MCVD/VAD processes as well where the downstream pressure is higher.

Any process descriptions or blocks in flow charts should be understood as representing modules, segments, or portions of code which include one or more executable instructions for implementing specific logical functions or steps in the process, and alternate implementations are included within the scope of the preferred embodiment of the present disclosure in which functions may be executed out of order from that shown or discussed, including substantially concurrently or in reverse order, depending on the functionality involved, as would be understood by those reasonably skilled in the art of the present disclosure.

What is claimed is:

1. Vapor delivery system for depositing chemical reactants, the vapor delivery system comprising:
a first volume connected to a vaporizer; and
a second volume connected to the first volume and delivers one or more vaporized chemical reactants to downstream,
wherein the second volume is smaller than the first volume.

2. Vapor delivery system of claim 1, the vapor delivery system is used for optical fiber preform manufacturing processes.

3. Vapor delivery system of claim 2, the optical fiber preform manufacturing processes is plasma chemical vapor deposition, and one or more vaporized chemical reactants are delivered into an inner surface of a substrate tube.

4. Vapor delivery system of claim 1 further comprises a fixed flow restrictor connected to the second volume, and the fixed flow restrictor delivers the one or more vaporized chemical reactants to the downstream.

5. Vapor delivery system of claim 4, wherein the fixed flow restrictor buffers downstream fluctuations.

6. Vapor delivery system of claim 1, wherein the second volume is sufficiently small to allow quick response time.

7. Vapor delivery system of claim 6, wherein the size of the second volume is approximately 30% or less of the size of the first volume.

8. Vapor delivery system of claim 1, wherein the first volume buffers upstream fluctuations.

9. Vapor delivery system of claim 1 further comprises a first pressure sensor that measure the pressure inside of the first volume, a second pressure sensor that measure the pressure inside of the second volume, a first control valve placed upstream of the first volume, and a second control valve placed between the first volume and the second volume, wherein pressure change in the first pressure sensor determines the setting of the first control valve and pressure change in the second pressure sensor determines the setting of the second control valve.

10. Apparatus for performing plasma chemical vapor deposition along an inner surface of a substrate tube, the apparatus comprising:
vapor delivery system that delivers one or more chemical reactants into the inner surface of the substrate tube
wherein the vapor delivery system comprises:
a first volume connected to a vaporizer; and
a second volume connected to the first volume and delivers the one or more vaporized chemical reactants into the inner surface of the substrate tube,
wherein the second volume is smaller than the first volume.
